(19) United States
(12) Patent Application Publication
(10) Pub. No.: US 2019/0199333 A1
(43) Pub. Date: Jun. 27, 2019

(54) SEMICONDUCTOR DEVICE

(71) Applicant: RENESAS ELECTRONICS CORPORATION, Tokyo (JP)

(72) Inventor: Takayuki Hotaruhara, Tokyo (JP)

(21) Appl. No.: 16/176,423

(22) Filed: Oct. 31, 2018

(30) Foreign Application Priority Data
Dec. 21, 2017 (JP) 2017-245271

(51) Int. Cl. H03K 5/13; H03K 5/24

(52) U.S. Cl. CPC H03K 5/13; H03K 2005/00019; H03K 5/24

(57) ABSTRACT

The present disclosure provides a semiconductor device that can achieve stable data communication with a simple method. The semiconductor device includes: a plurality of signal lines; a driver circuit that is provided corresponding to the signal lines and transmits a plurality of data in parallel by driving each of the signal lines; a plurality of delay circuits that are provided corresponding to each of the signal lines and can variably set the delay amount of data transmitted to the signal line; and a timing adjustment circuit for setting the delay amount of a corresponding signal line based on data of an adjacent signal line among the signal lines.

### CROSS-REFERENCE TO RELATED APPLICATIONS

The disclosure of Japanese Patent Application No. 2017-245271 filed on Dec. 21, 2017 including the specification, drawings and abstract is incorporated herein by reference in its entirety.

### BACKGROUND

The present disclosure relates to techniques that are effective when applied to a semiconductor device, for example, a circuit with a parallel interface.

With the advancement in information processing technology, semiconductor devices capable of achieving high speed and low power consumption are becoming more popular.

In such semiconductor devices, for example, there is known technology relating to semiconductor storage devices based on data strobe signal (DQS) to achieve high speed data communication.

As examples of semiconductor storage devices based on data strobe signal (DQS), there are semiconductor storage devices with a data transfer rate of Gbps band, such as, for example, DDR4 SDRAM (Double Data Rate 4 Synchronous DRAM).

In general, a memory interface is provided between such a high speed semiconductor storage device and a central processing unit (CPU).

In this regard, a technique is disclosed that performs calibration of synchronous timing due to the fluctuation of data (Patent Document 1: Japanese Unexamined Patent Application Publication No. 2010-86246).

### SUMMARY

On the other hand, in the case of parallel interface, there is a possibility that signal delay may occur due to the influence of crosstalk between adjacent signal lines. This signal delay causes a deviation of synchronous timing and so is an important problem in achieving high speed.

The present disclosure has been made to solve the above problem and an object thereof is to provide a semiconductor device capable of achieving stable data communication with a simple method.

Other objects and novel features will be apparent from the description of the present specification and the accompanying drawings.

A semiconductor device according to an aspect of the present disclosure includes a plurality of signal lines, as well as a driver circuit provided corresponding to the signal lines to transmit a plurality of data in parallel by driving each of the signal lines. Further, the semiconductor device also includes a plurality of delay circuits that are provided corresponding to each of the signal lines and can variably set the delay amount of data transmitted to the signal line, as well as a timing adjustment circuit for setting the delay amount of a corresponding signal line based on data of an adjacent signal line among the signal lines.

According to an embodiment, a semiconductor device can achieve stable data communication with a simple method.

### BRIEF DESCRIPTION OF THE DRAWINGS

FIG. 1 is a diagram showing the configuration of a semiconductor device 1 based on a first embodiment;

FIG. 2 is a timing chart of an interface circuit based on the first embodiment;

FIG. 3 is a diagram showing an example of an adjustment table of a timing adjustment circuit 200 with respect to data D1 based on the first embodiment;

FIGS. 4A and 4B are diagrams showing the relationship between adjustment values based on the first embodiment;

FIG. 5 is a diagram showing the configuration of a semiconductor device 1# based on a second embodiment; and

FIG. 6 is a timing chart of an interface circuit based on the second embodiment.

### DETAILED DESCRIPTION

Preferred embodiments of the present disclosure will be described in detail with reference to the accompanying drawings. It is to be noted that like or corresponding parts are designated by like reference numerals throughout the accompanying drawings, and thus their description will not be repeated.

### First Embodiment

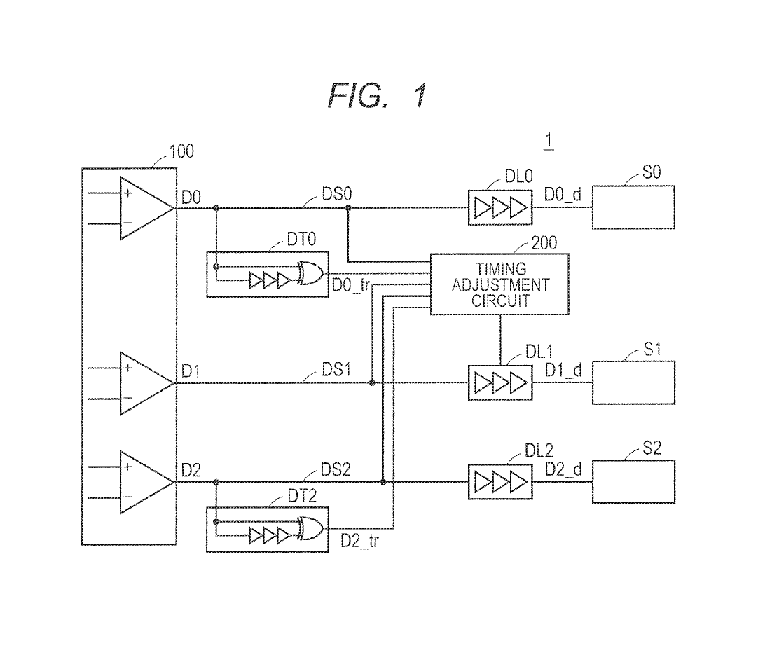

FIG. 1 is a diagram showing the configuration of a semiconductor device 1 based on a first embodiment.

As shown in FIG. 1, the semiconductor device 1 includes an interface circuit.

More specifically, a parallel interface circuit will be described.

The semiconductor device 1 includes a plurality of signal lines DS0 to DS2 (hereinafter, also correctively referred to as signal line DS), as well as a driver circuit 100 provided corresponding to the signal lines to transmit a plurality of data D0 to D2 in parallel by driving each of the signal lines DS0 to DS2. The semiconductor device 1 includes: a plurality of delay circuits DL0 to DL2 (hereinafter, also correctively referred to as delay circuit DL) that are provided corresponding to each of the signal lines DS0 to DS2 and can variably set the delay amount of data transmitted to the signal line; and sampling circuits S0 to S2 for sampling each of the data of the delay circuits DL0 to DL2. Further, the semiconductor device 1 also includes; a timing adjustment circuit for setting the delay amount of a corresponding signal line based on data of an adjacent signal line; and signal change detection circuits DT0 and DT2 that are provided corresponding to each of the signal lines DS0 and DS2.

In this example, a method for setting the delay amount of the delay circuit DL1 of the signal line DS1 is described as an example.

As an example, the driver circuit 100 includes a plurality of comparators. Each comparator outputs data D to the corresponding signal line DS based on the comparison between a reference voltage and an input voltage. In this example, the driver circuit 100 outputs read data D0 to D2 to each of the signal lines DS0 to DS2 as an example.

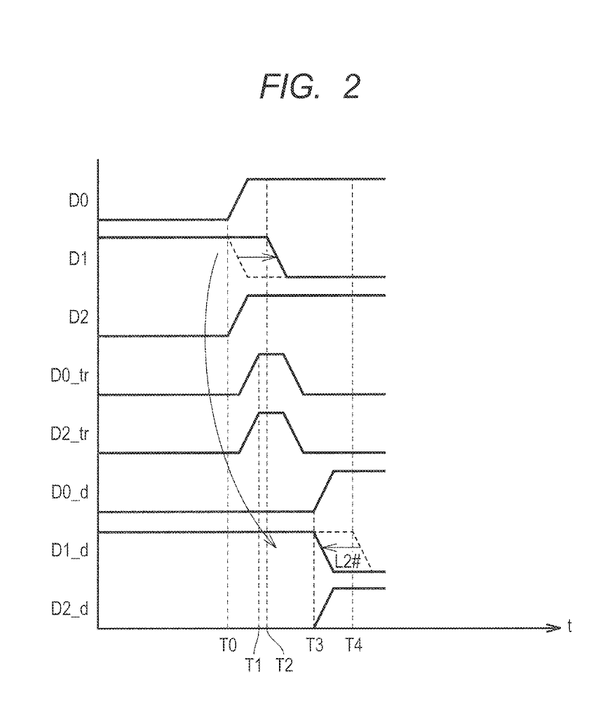

FIG. 2 is a timing chart of the interface circuit based on the first embodiment.

Referring to FIG. 2, it shows that the data D0 of the signal line DS0 changes from “L” level to “H” level with respect to the signal at time T0. The data D2 of the signal line DS2 changes from “L” level to “H” level.

The data D1 of the signal line DS1 changes from “H” level to “L” level at time T2. It is ideal that the signal changes from “H” level to “L” level in the signal line DS1 at time T0, but it is shown that the fall period is delayed by a given period of time due to the influence of crosstalk of signal change in the signal lines DS0 and DS2.

Thus, when a delay amount of a fixed value is added in the delay circuits DL0 to DL2, the data D1 of the signal line DS1 lags behind other data.

At time T3, data D0_d and D2_2 through the delay circuits DL0 and DL2 are output.

At time T4, there is a possibility that delayed data D1_d through the delay circuit DL1 may be output due to the influence of crosstalk.

In this example, the delay amount is adjusted with respect to the signal line DS1. More specifically, the delay amount is adjusted to a value that cancels the delay due to the influence of crosstalk of signal change in the signal lines DS0 and DS2. This example shows the case in which the delay amount is adjusted by adjustment value L2#.

In this way, it is possible to align the synchronous timing of the sampling circuits S by cancelling the influence of the crosstalk.

In this example, the data D0 and D2 change at time T1.

The signal change detection circuits DT0 and DT2 detect the particular change and transit from “L” level to “H” level, respectively.

The timing adjustment circuit 200 obtains data of the signal lines DS0 and DS2, respectively, based on data D0_tr and D2_tr that are input from the signal change detection circuits DT0 and DT2.

When the data D0_tr and D2_tr are “H” level, the timing adjustment circuit 200 obtains the data D0 and D2 transmitted to the signal lines D20 and DS2. The timing adjustment circuit 200 adjusts the delay amount based on the combination of the obtained data D0, D2 and the data D1 transmitted to the signal line DS1.

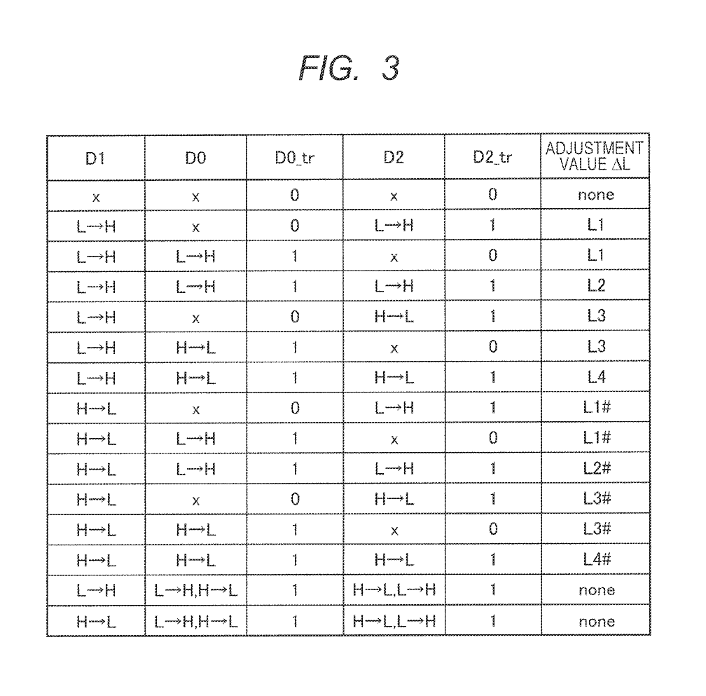

FIG. 3 is a diagram showing an example of the adjustment table of the timing adjustment circuit 200 with respect to the data D1 based on the first embodiment.

Referring to FIG. 3, this shows a table for adjusting the adjustment value ΔL based on the state of the data D1 as well as the state of the data D0 and D2.

With respect to the data D1, when there is no signal change “x”, the adjustment value is 0 (none).

In the case in which the data D1 transits from “L” level to “H” level, when the data D2 transits from “L” level to “H” level, the signal timing is affected by crosstalk. In this case, the timing adjustment circuit 200 sets the adjustment value to adjustment value L1. The state of the data D0 is the state of no signal change.

In the case in which the data D1 transits from “L” level to “H” level, when the data D0 transits from “L” level to “H” level, the signal timing is affected by crosstalk. In this case, the timing adjustment circuit 200 sets the adjustment value to adjustment value L1. The state of the data D1 is the state of no signal change.

In the case in which the data D1 transits from “L” level to “H” level, when the data D0 transits from “L” level to “H” level and when the data D2 changes from “L” level to “H” level, the signal timing is affected by crosstalk. In this case, the timing adjustment circuit 200 sets the adjustment value to adjustment value L2.

In the case in which the data D1 transits from “L” level to “H” level, when the data D2 transits from “H” level to “L” level, the signal timing is affected by crosstalk. In this case, the timing adjustment circuit 200 sets the adjustment value to adjustment value L3. The state of the data D0 is the state of no signal change.

In the case in which the data D1 transits from “L” level to “H” level, when the data D0 transits from “H” level to “L” level, the signal timing is affected by crosstalk. In this case, the timing adjustment circuit 200 sets the adjustment value to the adjustment value L3. The state of the data D1 is the state of no signal change.

In the case in which the data D1 transits from “L” level to “H” level, when the data DO transits from “H” level to “L” level and the data D2 changes from “H” level to “L” level, the signal timing is affected by crosstalk. In this case, the timing adjustment circuit 200 sets the adjustment value to adjustment value L4.

In the case in which the data D1 transits from “H” level to “L” level, when the data D2 transits from “L” level to “H” level, the signal timing is affected by crosstalk. In this case, the timing adjustment circuit 200 sets the adjustment value to adjustment value L1#. The state of the data D0 is the state of no signal change.

In the case in which the data D1 transits from “H” level to “L” level, when the data D0 transits from “L” level to “H” level, the signal timing is affected by crosstalk. In this case, the timing adjustment circuit 200 sets the adjustment value to the adjustment value L1#. The state of the data D1 is the state of no signal change.

In the case in which the data D1 transits from “H” level to “L” level, when the data D0 transits from “L” level to “H” level and the data D2 transits from “L” level to “H” level, the signal timing is affected by crosstalk. In this case, the timing adjustment circuit 200 sets the adjustment value to adjustment value L2#.

In the case in which the data D1 transits from “H” level to “L” level, when the data D2 transits from “H” level to “L” level, the signal timing is affected by crosstalk. In this case, the timing adjustment circuit 200 sets the adjustment value to adjustment value L3#. The state of the data D0 is the state of no signal change.

In the case in which the data D1 transits from “H” level to “L” level, when the data D0 transits from “H” level to “L” level, the signal timing is affected by crosstalk. In this case, the timing adjustment circuit 200 sets the adjustment value to the adjustment value L3#. The state of the data D1 is the state of no signal change.

In the case in which the data D1 transits from “H” level to “L” level, when the data D0 transits from “H” level to “L” level and the data D2 transits from “H” level to “L” level, the signal timing is affected by crosstalk. In this case, the timing adjustment circuit 200 sets the adjustment value to adjustment value L4#.

In the case in which the data D1 transits from “L” level to “H” level, when the data D0 transits from “L” level to “H” level and the data D2 transits from “H” level to “L” level, or when the data D0 transits from “H” level to “L” level and the data D2 transits from “L” level to “H” level, the logic levels of the data of the adjacent signal lines DS are opposite to each other, so that crosstalk does not occur. For this reason, in this case, the adjustment value is 0 (none).

In the case in which the data D1 transits from “H” level to “L” level, when the data D0 transits from “L” level to “H” level and the data D2 transits from “H” level to “L” level, or when the data D0 transits from “H” level to “L” level and the data D2 transits from “L” level to “H” level, the logic levels of the data of the adjacent signal lines DS are opposite to each other, so that crosstalk does not occur. For this reason, in this case, the adjustment value is 0 (none).

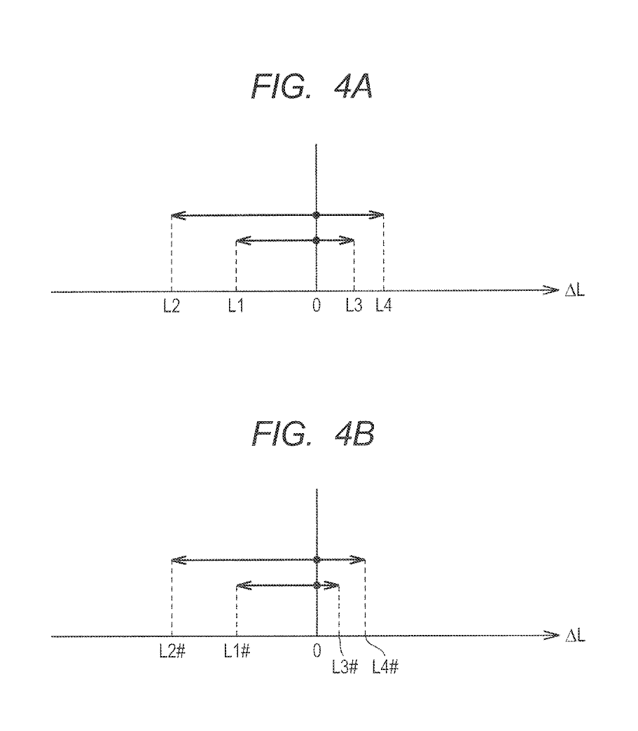

FIGS. 4A and 4B are diagrams showing the relationship of adjustment values based on the first embodiment.

Referring to FIG. 4A, this shows the relationship of the adjustment values L1 to L4.

The adjustment values L1 and L2 that are set as adjustment value ΔL are negative. On the other hand, the adjustment values L3 and L4 are positive. The adjustment values L1 and L2 satisfy the relationship |L2|>|L1|. The adjustment values L3 and L4 satisfy the relationship L4>L3.

In the case in which the data D1 transits from “L” level to “H” level, when the data D0 transits from “L” level to “H” level and the data D2 transits from “L” level to “H” level, the signal timing is affected by crosstalk more than when only either one of the data D0 and D2 transits. For this reason, it is necessary to increase the adjustment value of the delay amount.

In the case in which the data D1 transits from “L” level to “H” level, when the data D0 transits from “H” level to “L” level and the data D2 transits from “H” level to “L” level, the signal timing is affected by crosstalk more than when only either one of the data D0 and D2 transits. For this reason, it is necessary to increase the adjustment value of the delay amount.

Referring to FIG. 4B, this shows the relationship of the adjustment values L1# to L4#.

The adjustment values L1# and L2# that are set as adjustment value ΔL are negative. On the other hand, the adjustment values L3# and L4# are positive. The adjustment values L1# and L2# satisfy the relationship |L2#|>|L1#1|. The adjustment values L3# and L4# satisfy the relationship L4#>L3#.

In the case in which the data D1 transits from “H” level to “L” level, when the data D0 transits from “L” level to “H” level and the data D2 transits from “L” level to “H” level, the signal timing is affected by crosstalk more than when only either one of the data D0 and D2 transits. For this reason, it is necessary to increase the adjustment value of the delay amount.

In the case in which the data D1 transits from “H” level to “L” level, when the data D0 transits from “H” level to “L” level and the data transits from. “H” level to “L” level, the signal timing is affected by crosstalk more than when only either one of the data D0 and D2 transits. For this reason, it is necessary to increase the adjustment value of the delay amount.

With this method, it is possible to adjust the delay amount of the delay circuit DL1 of the signal line DS1 to a value that cancels the influence of the crosstalk between adjacent signal lines DS.

Note that while this example has described the configuration in which the timing adjustment circuit 200 is provided for the signal line DS1, it is also possible to provide the timing adjustment circuit 200 can also be provided corresponding to each signal line DS according to the same method. With this configuration, it is possible to cancel the influence of crosstalk on each of the signal lines DS. As a result, it is possible to increase the effective window width for sampling a plurality of data in a plurality of sampling circuits S, and thus increase the speed of the process.

Further, the signal change detection circuits DT0 and DT2 respectively output detection signals D0_tr and D2_tr (“H” level) that detect the transition of the signal level of the signal lines DS0 and DS2.

The timing adjustment circuit 200 obtains the signal level of the signal lines DS0 and DS2 according to the detection signal D0_tr and D2_tr. Thus, the timing adjustment circuit 200 can reliably obtain the transited data of the signal lines DS0 and DS2 with the detection signal D0_tr and D2_tr as a trigger.

In this way, it is possible to reliably set the adjustment value ΔL according to the adjustment table of FIG. 3.

The adjustment table of FIG. 3 can be set by tests.

For example, the tests can use data output from a memory provided in the semiconductor device. Based on this data, the driver circuit 100 drives the signal line DS by using a predetermined data pattern.

For example, the driver circuit 100 drives the signal line DS according to alternating data patterns such as “101010”. It is also possible to set the adjustment table by detecting the delay difference by the delay circuit DL according to this drive. Various data patterns can be set.

### Second Embodiment

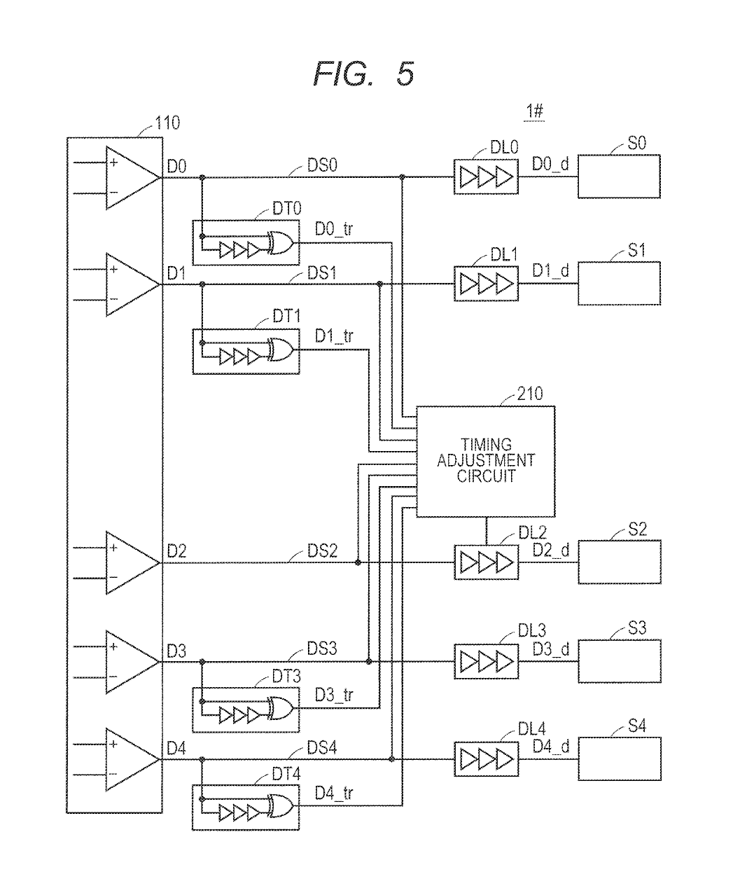

FIG. 5 is a diagram showing the configuration of a semiconductor device 1# based on a second embodiment.

As shown in FIG. 5, the semiconductor device 1# includes an interface circuit.

More specifically, a parallel interface circuit will be described.

The semiconductor device 1# includes a plurality of signal lines DS0 to DS5, and a driver circuit 100 provided corresponding to the signal lines to transmit a plurality of data D0 to D5 in parallel by driving each of the signal lines DS0 to DS5. The semiconductor device 1# also includes: a plurality of delay circuits DL0 to DL5 that are provided corresponding to each of the signal lines DS0 to DS5 and can variably set the delay amount of the data transmitted to the signal line; and sampling circuits S0 to S5 for sampling data of each of the delay circuits DL0 to DL5.

Further, the semiconductor device 1# includes a timing adjustment circuit 210 for setting the delay amount of a corresponding signal line based on data of an adjacent signal line, as well as signal change detection circuits DT0, DT1, DT3, and DT4 that are provided corresponding to each of the signal lines DS0, DS1, DS3, and DS4.

In this example, a method for setting the delay amount of the delay circuit DL2 of the signal line DS2 is described as an example.

As an example, the driver circuit 110 includes a plurality of comparators. Each comparator outputs data D to a corresponding signal line DS based on the comparison between a reference voltage and an input voltage. In this example, the driver circuit 110 outputs, as an example, read data D0 to D5 to each of the signal lines DS0 to DS5.

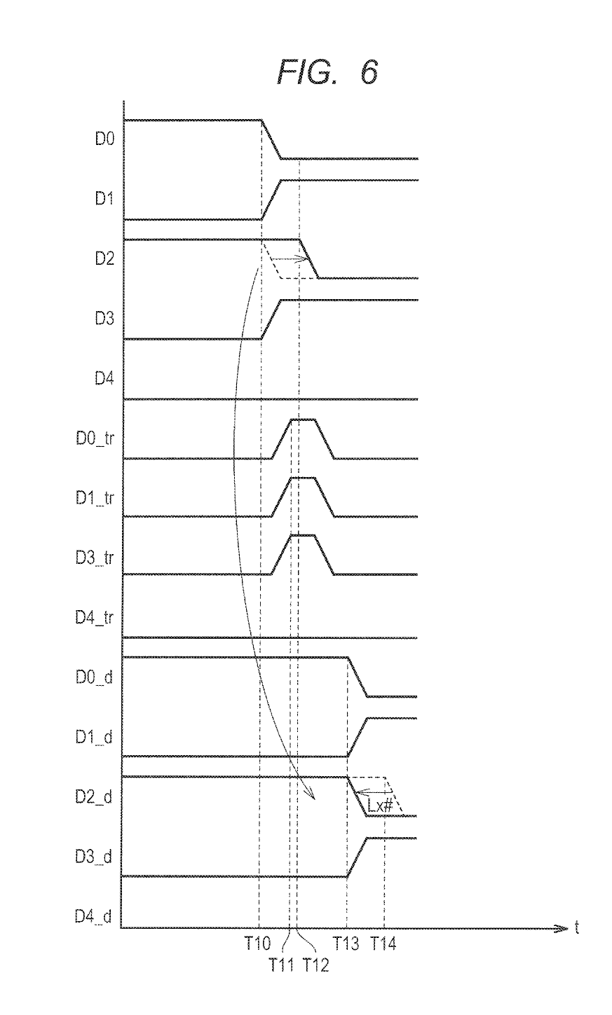

FIG. 6 is a timing chart of the interface circuit based on the second embodiment.

Referring to FIG. 6, it shows that the data D0 of the signal line DS0 changes from “H” level to “L” level at time T10. The data D1 of the signal line DS1 changes from “L” level to “H” level. The data D3 of the signal line DS3 changes from “L” level to “H” level. The data D4 of the signal line DS4 maintains “L” level.

At T11, the data D2 of the signal line DS2 changes from “H” level to “L” level. It is ideal that the signal changes from “H” level to “L” level in the signal line DS2 at time T10, but it is shown that the rise period is delayed by a given period of time due to the influence of crosstalk of signal change in the signal lines DS0, DS1, and DS3.

Thus, when a delay amount of a fixed value is added in the delay circuits DL0, DL1, and DL3, the data D2 of the signal line DS2 lags behind other data.

At time T13, the data D0_d, D1_d, and D3_d through the delay circuits DL0, DL1, and DL3 are output.

There is a possibility that delayed data D2_d through the delay circuit DL2 is output due to the influence of crosstalk at time T14.

In this example, the delay amount is adjusted with respect to the data D2 of the signal line DS2. More specifically, the delay amount is adjusted to a value that cancels the delay due to the influence of crosstalk of signal change in the signal lines DS0, DS1, DS3, and DS4. This example shows the case in which the delay amount is adjusted by adjustment value Lx#.

In this way, it is possible to align the synchronous timing of the sampling circuits S by cancelling the influence of the crosstalk.

In this example, the data D0, D1, and D2 change at time T10.

The signal change detection circuits DT0, DT1, and DT3 detect the particular change and transit from “L” level to “H” level, respectively.

The timing adjustment circuit 210 obtains the data of the signal lines DS0, DS1, and DS3, respectively, based on the data D0_tr, D1_tr, and D3_tr that are input from the signal change detection circuits DT0, DT1, and DT3.

When the data D0_tr, D1_tr, and D3_tr are “H” level, the timing adjustment circuit 210 obtains the data D0, D1, and D3 that are transmitted to the signal lines DS0, DS1, and DS3. The timing adjustment circuit 210 adjusts the delay amount based on the combination of the obtained data D0, D1, D3 and the data D2 transmitted to the signal line DS2.

More specifically, the timing adjustment circuit 210 adjusts the adjustment value ΔL based on the state of the data D0, D1, and D3, based on the same adjustment table as described in the first embodiment.

Note that this example has described the case in which the state of the data D4 is not used because there is no change in the data transmitted to the signal line DS4. However, when there is a change in the data transmitted to the signal line DS4, the adjustment value ΔL is also adjusted for the data D4 in the same way as described above.

With this method, it is possible to adjust the delay amount of the delay circuit DL2 of the signal line DS2 to a value that cancels the influence of crosstalk of adjacent signal lines DS.

In the second embodiment, the semiconductor device cancels the influence of crosstalk of adjacent four signal lines DS. In other words, it is possible to adjust the adjustment value to a highly accurate value ΔL. As a result, it is possible to increase the effective window width for sampling a plurality of data in the sampling circuits S, and thus increase the speed of the process. In other words, it is possible to achieve stable data communication with a simple method.

Note that while this example has described the configuration in which the timing adjustment circuit 210 is provided for the signal line DS2, the timing adjustment circuit 210 can also be provided corresponding to each of the signal lines DS according to the same method. In this way, it is possible to cancel the influence of crosstalk on each signal line DS.

The present disclosure has been described in detail based on preferred embodiments. However, the present disclosure is not limited to the specific embodiments and it goes without saying that the present disclosure can be variously modified without departing from the scope thereof.

What is claimed is:

1. A semiconductor device comprising:
a plurality of signal lines;
a driver circuit that is provided corresponding to each of the signal lines and transmits a plurality of data in parallel by driving each of the signal lines;
a plurality of delay circuits that are provided corresponding to each of the signal lines and can variably set the delay amount of data transmitted to the signal line, and
a timing adjustment circuit for setting the delay amount of a corresponding signal line based on data of an adjacent signal line among the signal lines.

2. The semiconductor device according to claim 1,
wherein the timing adjustment circuit sets the delay amount of the corresponding signal line based on the input of data indicating the presence or absence of signal change in the adjacent signal line, the input of data of adjacent signal lines, and the input of data of the corresponding signal line.

3. The semiconductor device according to claim 2,
wherein the timing adjustment circuit obtains the data of the adjacent signal line according to the input of the data indicating the presence or absence of signal change in the adjacent signal line, and sets the delay amount of the corresponding signal line based on the combination between the input of the obtained data of the adjacent signal line and the input of data of the corresponding signal line.

4. The semiconductor device according to claim 1,
wherein the timing adjustment circuit sets the delay amount of a corresponding signal line based on the data of two adjacent signal lines among the signal lines.

5. The semiconductor device according to claim 4,
wherein, when the signal change in two adjacent signal lines among the signal lines changes to the same data, the timing adjustment circuit increases the adjustment value of the delay amount by comparing with the case of the signal change in one signal line.

6. The semiconductor device according to claim 1,
wherein the timing adjustment circuit increases the delay amount when the data of the signal change in the adjacent signal line is the same as the data of the signal change in the corresponding signal line, and
wherein the timing adjustment circuit reduces the delay amount when the data of the signal change in the adjacent signal lines is opposite to the data of the signal change in the corresponding signal line.

7. The semiconductor device according to claim 1,
wherein the timing adjustment circuit sets the delay amount of a corresponding signal line based on the data of four adjacent signal lines among the signal lines.
